(19) United States
(12) Patent Application Publication
(10) Pub. No.: US 2016/0218268 A1
(43) Pub. Date: Jul. 28, 2016

(54) THERMOELECTRIC CONVERSION MODULE

(71) Applicant: FUJIFILM Corporation, Tokyo (JP)

(72) Inventors: Yoichi MARUYAMA, Ashigara-kami-gun (JP); Naoyuki HAYASHI, Ashigara-kami-gun (JP)

(73) Assignee: FUJIFILM Corporation, Tokyo (JP)

(21) Appl. No.: 15/088,237

(22) Filed: Apr. 1, 2016

Related U.S. Application Data
(63) Continuation of application No. PCT/JP2014/075836, filed on Sep. 29, 2014.

(30) Foreign Application Priority Data
Oct. 3, 2013 (JP) 2013-208383

(51) Int. Cl. H01L 35/32; H01L 35/24

(52) U.S. Cl. CPC H01L 35/32; H01L 35/24

(57) ABSTRACT

Provided is a thermoelectric conversion module in which the warping degree of the thermoelectric conversion module can be adjusted, the adhesiveness for being attached to a heat source such as a pipe improves, and the degradation of the thermoelectric performance can be prevented. This object is achieved by a thermoelectric conversion module having a flexible substrate and a thermoelectric conversion element having a first electrode, a thermoelectric conversion layer including an organic material, and a second electrode in this order, in which the thermoelectric conversion module has a stress relaxation layer that adjusts warping of the flexible substrate on a surface of the flexible substrate opposite to the thermoelectric conversion element and warps so as to become concave with respect to a thermoelectric conversion element side.

### CROSS-REFERENCE TO RELATED APPLICATIONS

This application is a Continuation of PCT International Application No. PCT/JP2014/075836 filed on Sep. 29, 2014, which claims priority under 35 U.S.C. §119(a) to Japanese Patent Application No. 2013-208383 filed on Oct. 3, 2013. Each of the above applications is hereby expressly incorporated by reference, in its entirety, into the present application.

### BACKGROUND OF THE INVENTION

1. Field of the Invention

The present invention relates to a thermoelectric conversion module.

2. Description of the Related Art

Thermoelectric conversion materials that can mutually convert heat energy and electric energy are used in power generating elements that generate power using heat and in thermoelectric conversion elements such as Peltier devices.

Thermoelectric conversion elements are capable of directly converting heat energy to electric power and have an advantage of not requiring any moving parts. Therefore, when a power generating element (thermoelectric conversion module) in which a thermoelectric conversion element is used is provided at a site at which heat is exhausted, for example, an incinerator or a variety of facilities in a plant, it is possible to easily obtain electric power without the need of paying for operational costs.

In order to provide the above-described thermoelectric conversion module on the surfaces of portions having a variety of shapes, for example, the surface of a cylindrical portion having a curved surface such as a heat exhaust pipe, it is necessary to provide flexibility to the thermoelectric conversion module.

Therefore, it is considered that an organic material is used as a thermoelectric conversion material, thereby obtaining a thermoelectric conversion module having a light weight or favorable flexibility.

As an example, WO2012/133314A describes a thermoelectric conversion element including “an electroconductive composition containing (A) a carbon nanotube, (B) an electroconductive polymer. and (C) an onium salt compound” (refer to claim 1) provided on a substrate as an electroconductive film.

### SUMMARY OF THE INVENTION

A thermoelectric conversion module having flexibility can be produced by applying and drying a thermoelectric conversion material on a flexible substrate so as to form a thermoelectric conversion layer. However, a thermoelectric conversion material made of an organic material shrinks while being dried, and thus, when a thermoelectric conversion layer is formed on a flexible substrate, the produced thermoelectric conversion module significantly warps toward the thermoelectric conversion layer side. When the thermoelectric conversion module significantly warps, there is a problem in that, when attached to a heat source such as a heat exhaust pipe, the thermoelectric conversion module is peeled off and is not sufficiently adhered to the heat source, and thus the thermoelectric performance degrades.

Therefore, an object of the invention is to provide a thermoelectric conversion module in which the warping degree of the thermoelectric conversion module can be adjusted, the adhesiveness for being attached to a heat source such as a pipe improves, and the degradation of the thermoelectric performance can be prevented.

The present inventors carried out intensive studies in order to solve the above-described problem and thus found that, when a thermoelectric conversion module has a stress relaxation layer that adjusts the warping of a flexible substrate on a surface of the flexible substrate opposite to a thermoelectric conversion element and warps so as to become concave with respect to the thermoelectric conversion element side, it is possible to adjust the warping degree of the thermoelectric conversion module, the adhesiveness is improved when the thermoelectric conversion module is attached to a heat source such as a pipe, and the degradation of the thermoelectric performance can be prevented, and the inventors completed the invention.

That is, the inventors found that the above-described problem can be solved using the following constitutions.

(1) A thermoelectric conversion module having a flexible substrate and a thermoelectric conversion element having a first electrode, a thermoelectric conversion layer including an organic material, and a second electrode in this order, in which the thermoelectric conversion module has a stress relaxation layer that adjusts warping of the flexible substrate on a surface of the flexible substrate opposite to the thermoelectric conversion element and warps so as to become concave with respect to a thermoelectric conversion element side.

(2) The thermoelectric conversion module according to (1), in which the stress relaxation layer is a heat-dissipating sheet.

(3) The thermoelectric conversion module according to (1) or (2), in which the stress relaxation layer includes the same material as the thermoelectric conversion layer.

(4) The thermoelectric conversion module according to any one of (1) to (3), in which a stress relaxation force of the stress relaxation layer is anisotropic in a predetermined first direction and a direction orthogonal to the first direction.

(5) The thermoelectric conversion module according to any one of (1) to (4), in which a warping degree of the thermoelectric conversion module is 50 μm to 80 mm.

(6) The thermoelectric conversion module according to any one of (1) to (5), in which the thermoelectric conversion layer contains an electroconductive polymer.

(7) The thermoelectric conversion module according to any one of (1) to (5), in which the thermoelectric conversion layer contains a carbon nanotube and a binder.

(8) The thermoelectric conversion module according to any one of (1) to (7), in which the flexible substrate is formed of an organic material.

(9) The thermoelectric conversion module according to any one of (1) to (8), in which a thickness of the flexible substrate is 5 μm to 5,000 μm.

As described below, according to the invention, it is possible to provide a thermoelectric conversion module in which the warping degree of the thermoelectric conversion module can be adjusted, the adhesiveness for being attached to a heat source such as a pipe improves, and the degradation of the thermoelectric performance can be prevented.

### BRIEF DESCRIPTION OF THE DRAWINGS

FIG. 1 is a sectional view conceptually illustrating an example of a thermoelectric conversion module of the invention.

FIG. 2 is a sectional view conceptually illustrating the warping of the thermoelectric conversion module illustrated in FIG. 1.

FIGS. 3A and 3B are rear views conceptually illustrating another example of the thermoelectric conversion module of the invention.

FIG. 4 is a sectional view conceptually illustrating still another example of the thermoelectric conversion module of the invention.

### DESCRIPTION OF THE PREFERRED EMBODIMENTS

### Thermoelectric Conversion Module

The thermoelectric conversion module of the invention is a thermoelectric conversion module having a flexible substrate and a thermoelectric conversion element having a first electrode, a thermoelectric conversion layer including an organic material, and a second electrode in this order, in which the thermoelectric conversion module has a stress relaxation layer that adjusts warping of the flexible substrate on a surface of the flexible substrate opposite to the thermoelectric conversion element and warps so as to become concave with respect to the thermoelectric conversion element side.

In the thermoelectric conversion module of the invention, the stress relaxation layer is provided on the rear surface side, thereby suppressing the degree of warping caused by the shrinkage of the thermoelectric conversion layer, and the thermoelectric conversion module is warped toward the thermoelectric conversion element side, whereby the adhesiveness for being attached to a heat source such as a pipe is improved, and the degradation of the thermoelectric performance can be prevented.

Hereinafter, the thermoelectric conversion module of the invention will be described in detail on the basis of preferred examples illustrated in the accompanying drawings.

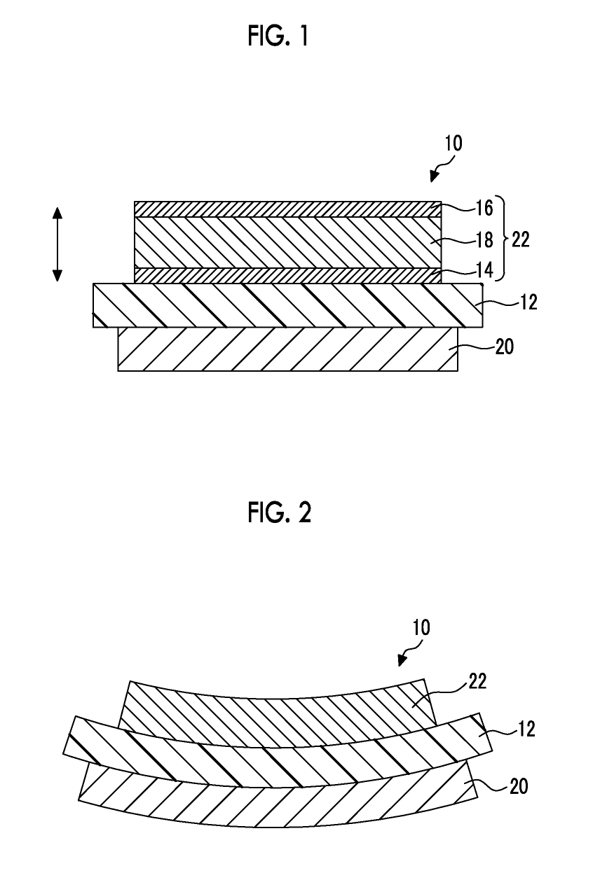

FIG. 1 is a sectional view conceptually illustrating an example of a thermoelectric conversion module of the invention.

A thermoelectric conversion module 10 illustrated in FIG. 1 has a flexible substrate 12, a thermoelectric conversion element 22 which has an electrode pair (a pair of electrodes) consisting of a first electrode 14 and a second electrode 16 and a thermoelectric conversion layer 18 sandwiched between the electrode pair and is disposed on one surface of the flexible substrate 12, and a stress relaxation layer 20 disposed on a surface of the flexible substrate 12 opposite to the thermoelectric conversion element 22.

As described above, since the stress relaxation layer 20 is provided on the surface opposite to the thermoelectric conversion element 22, even in case in which the flexible substrate 12 is used, it is possible to suppress and adjust the warping degree of the thermoelectric conversion module.

The material of the stress relaxation layer will be described below in detail.

In addition, the thermoelectric conversion module 10 illustrated in FIG. 1 is an embodiment in which an electromotive force (voltage) is obtained using a temperature difference in a direction indicated by an arrow and is brought into contact with a heat source on the second electrode 16 side.

Here, as illustrated in FIG. 2, the thermoelectric conversion module 10 of the invention warps so as to become concave with respect to the thermoelectric conversion element 22 side. That is, the thermoelectric conversion module warps so as to become concave on a side which comes into contact with a heat source.

In the invention, since the thermoelectric conversion module 10 is warped so as to become concave with respect to the thermoelectric conversion element 22 side, that is, the side on which the thermoelectric conversion module comes into contact with a heat source, the adhesiveness is enhanced by preventing the peeling of the end parts when the thermoelectric conversion module 10 is attached to a heat source such as a heat exhaust pipe, and it is possible to improve the thermoelectric performance.

Meanwhile, in order to enhance the adhesiveness, the thermoelectric conversion module being flattened by eliminating warping can be considered. However, according to studies by the inventors, it has been found that, when the thermoelectric conversion module warps so as to become concave with respect to the attachment side, the adhesiveness further improves. When the adhesiveness to a heat source improves, the thermoelectric performance improves.

Here, the warping degree of the thermoelectric conversion module is not particularly limited as long as the adhesiveness can be improved when the thermoelectric conversion module is attached to a heat source, and the warping degree thereof is preferably 50 μm or higher and 8 cm or lower.

Meanwhile, the warping degree refers to the average of the maximum value and the minimum value of the peeling degree on one short side of a 29.6 cm×21 cm module sample that is left to stand on a flat surface after the module sample is fixed by placing a weight on a central part of the other side of the sample.

Here, the disposition of the stress relaxation layer 20 is not particularly limited, and the stress relaxation layer may be provided on the entire rear surface or a partial rear surface of the flexible substrate 12 as long as the warping degree of the thermoelectric conversion module 10 can be adjusted.

In addition, the stress relaxation force of the stress relaxation layer 20 may be made anisotropic. That is, the suppression degree of warping may be varied in every direction.

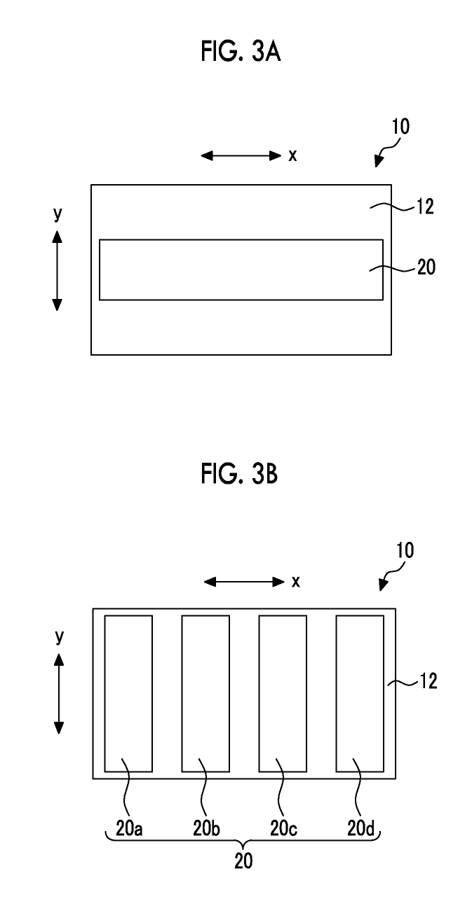

FIGS. 3A and 3B illustrate examples of the constitution of the stress relaxation layer 20 for making the stress relaxation force of the stress relaxation layer 20 anisotropic.

FIG. 3A is a rear view illustrating another example of the thermoelectric conversion module.

The thermoelectric conversion module 10 illustrated in FIG. 3A is a thermoelectric conversion module in which the stress relaxation layer 20 is formed on the rear surface side of the rectangular flexible substrate 12. Meanwhile, in the drawings, the horizontal direction is defined as the x direction, and the vertical direction is defined as the y direction.

As illustrated in the drawing, the stress relaxation layer 20 is formed on an area in the flexible substrate 12 which covers almost the entire side in the x direction and approximately a third of the side in the y direction from the central part.

When the stress relaxation layer 20 is formed as described above, it is possible to further increase the stress relaxation force in the x direction compared with in the y direction. That is, it is possible to make the stress relaxation stress anisotropic in the x direction and in the y direction.

FIG. 3B is a rear view illustrating another example of the thermoelectric conversion module.

The thermoelectric conversion module 10 illustrated in FIG. 3B is a thermoelectric conversion module in which four stress relaxation layers 20a to 20d are formed on the rear surface side of the rectangular flexible substrate 12. Meanwhile, in the drawings, the horizontal direction is defined as the x direction, and the vertical direction is defined as the y direction.

As illustrated in the drawing, the four stress relaxation layers 20a to 20d are arranged on the flexible substrate, in the y direction, in a length that is substantially the same length of the y-direction side of the flexible substrate 12 and, in the x direction, apart from each other in a length that is an eighth of the x-direction side of the flexible substrate 12.

Even when a plurality of stress relaxation layers is provided, it is possible to make the stress relaxation stress anisotropic in the x direction and in the y direction.

The thermoelectric conversion module is warped due to the shrinkage of the thermoelectric conversion layer while being formed in a two dimensional manner, that is, both in the x direction and in the y direction. Meanwhile, when a heat source to which the thermoelectric conversion module is attached is, for example, a heat exhaust pipe, the heat source has a cylindrical shape, and thus the heat source forms a curved surface in one direction and has a straight shape in a direction orthogonal to the above-described direction. Therefore, it is possible to adjust the degree of warping in accordance with the shape of a heat source to which the thermoelectric conversion module is attached by making the stress relaxation force anisotropic in the x direction and in the y direction so as to vary the degree of warping of the thermoelectric conversion module in the x direction and in the y direction, and the adhesiveness can be further improved.

Meanwhile, a constitution for making the stress relaxation stress of the stress relaxation layer anisotropic is not limited to the above-described constitutions. For example, the stress relaxation force can be made anisotropic by varying the thickness of the stress relaxation layer in every area or by adjusting the alignment direction of the material forming the stress relaxation layer.

In addition, the constitution for varying the degree of warping of the thermoelectric conversion module in every direction can also be realized by making the flexibility of the flexible substrate anisotropic.

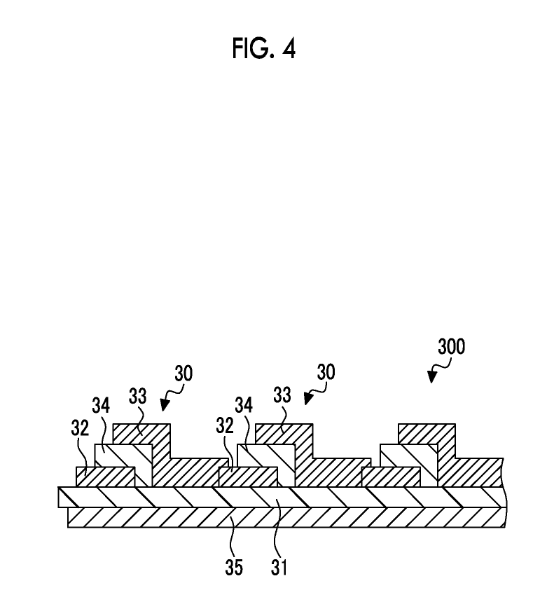

In addition, as illustrated in FIG. 4, the invention may be a thermoelectric conversion module 300 in which thermoelectric conversion elements 30 adjacent to each other and a common substrate 31 are used, and a second electrode 33 in one thermoelectric conversion element 30 is electrically connected to a first electrode 32 in another thermoelectric conversion element 30 adjacent to the above-described thermoelectric conversion element so as to connect the respective thermoelectric conversion elements 30 in series. In the thermoelectric conversion module 300, a stress relaxation layer 35 is formed on a surface (rear surface) side opposite to the surface on which a plurality of the thermoelectric conversion elements 30 is disposed. In addition, although not illustrated in the drawing, the thermoelectric conversion module 300 warps so as to become concave with respect to the surface side on which the thermoelectric conversion elements 30 are formed.

Next, the respective layers (the substrate, the electrode, the thermoelectric conversion layer, the stress relaxation layer, and the like) constituting the thermoelectric conversion module of the invention will be described in detail.

[Flexible Substrate]

The flexible substrate in the thermoelectric conversion module of the invention is not particularly limited, but a substrate which has desired flexibility and is not easily influenced during the formation of the electrode or the formation of the thermoelectric conversion layer is preferably selected.

Examples of the above-described substrate include a glass substrate, a transparent ceramic substrate, a metal substrate, and a plastic film, and, among these, a plastic film is preferred from the viewpoint of costs or bendability.

Specific examples of the plastic film include polyester films such as films of polyethylene terephthalate, polyethylene isophthalate, polyethylene naphthalate, polybutylene terephthalate, poly(1,4-cyclohexylene dimethylene terephthalate), polyethylene-2,6-phthalene dicarboxylate, and a polyester film of bisphenol A with iso- and terephthalic acid; polycycloolefine films such as a ZEONOR film (manufactured by Zeon Corp.), an ARTON film (manufactured by JSR Corp.), and SUMILITE FS1700 (manufactured by Sumitomo Bakelite Co., Ltd.); polyimide films such as KAPTON (manufactured by Du Pont-Toray Co., Ltd.), APICAL (manufactured by Kaneka Corp.), UPILEX (manufactured by Ube Industries, Ltd.), and POMIRAN (manufactured by Arakawa Chemical Industries, Ltd.); polycarbonate films such as PURE-ACE (manufactured by TEIJIN LIMITED), and ELMECH (manufactured by Kaneka Corp.); polyether ether ketone films such as SUMILITE FS1100 (manufactured by Sumitomo Bakelite Co., Ltd.); and polyphenyl sulfide films such as TORELINA (manufactured by Toray Industries, Inc.).

From the viewpoints of easy availability, heat resistance at 100° C. or higher, economic efficiency, and effectiveness, commercially available polyethylene terephthalate, polyethylene naphthalate, a variety of polyimides or polycarbonate films, and the like are preferred.

In the invention, the thickness of the substrate can be appropriately selected depending on the application purposes; however, from the viewpoint of flexibility, the thickness thereof is preferably 5 μm to 5,000 μm and more preferably 5 μm to 1,000 μm.

[Thermoelectric Conversion Element]

<Electrode>

The electrode in the thermoelectric conversion element of the invention is not particularly limited, and specific examples of a material thereof include transparent electrodes of ITO, ZnO, and the like; metal electrodes of silver, copper, gold, aluminum, and the like; carbon materials such as CNT and graphene; organic materials such as PEDOT/PSS; electroconductive pastes obtained by dispersing electroconductive fine particles of silver, carbon black, or the like; and electroconductive pastes containing a metal nanowire of silver, copper, aluminum, or the like.

<Thermoelectric Conversion Layer>

The thermoelectric conversion layer in the thermoelectric conversion module of the invention is not particularly limited as long as the thermoelectric conversion layer includes an organic material and may be a thermoelectric conversion layer in which the organic material is used as a thermoelectric conversion material or a binder. In the invention, the thermoelectric conversion layer preferably has a constitution obtained by dispersing an organic thermoelectric conversion material in a binder. That is, in the invention, the thermoelectric conversion layer is a layer consisting of an organic material (a layer including an organic material as a main component).

The thermoelectric conversion layer contains at least a thermoelectric conversion material. In addition, the thermoelectric conversion layer may contain a polymer material or an inorganic material.

(Thermoelectric Conversion Material)

A thermoelectric conversion material that the thermoelectric conversion layer, which is used in the thermoelectric conversion module of the invention, contains is not particularly limited, and it is possible to use a known organic material such as an electroconductive polymer or an electroconductive nanocarbon material or a known thermoelectric conversion material such as a nanometal material (a metal-containing electroconductive nanomaterial). In the invention, as the thermoelectric conversion material, an organic material such as an electroconductive polymer or an electroconductive nanocarbon material is preferably used, and an electroconductive polymer is particularly preferably used. In addition, the thermoelectric conversion material may be used singly, or two or more kinds thereof may be used in combination.

For example, when an electroconductive polymer and an electroconductive nanomaterial (particularly, CNT) are used in combination, the electroconductive nanomaterial does not aggregate in a composition and is uniformly dispersed, and the coatability of the composition improves. In addition, a composition having high electroconductive properties is obtained.

(Electroconductive Polymer)

In the invention, the electroconductive polymer that is used as the thermoelectric conversion material is not particularly limited, and a known electroconductive polymer can be used.

For example, as the electroconductive polymer, it is possible to use a polymer compound having a conjugated molecular structure. Here, the polymer having a conjugated molecular structure refers to a polymer having a structure in which single bonds and double bonds alternately continue in a carbon-carbon bond on the main chain of the polymer. In addition, the electroconductive polymer that is used in the invention does not need to be a high-molecular-weight compound at all times and may be an oligomer compound.

Examples of the above-described conjugated polymer include thiophene-based compounds, pyrrole-based compounds, aniline-based compounds, acetylene-based compounds, p-phenylene-based compounds, p-phenylene vinylene-based compounds, p-phenylene ethynylene-based compounds, p-fluorenylene vinylene-based compounds, polyacene-based compounds, polyphenanthrene-based compounds, metal phthalocyanine-based compounds, p-xylylene-based compounds, vinylene sulfide-based compounds, m-phenylene-based compounds, naphthalene vinylene-based compounds, p-phenylene oxide-based compounds, phenylene sulfide-based compounds, furan-based compounds, selenophene-based compounds, azo-based compounds, metal complex-based compounds, and conjugated polymers having a repeating unit derived from a monomer that is a derivative or the like obtained by introducing a substituent into the above-described compound.

As the above-described electroconductive polymer, it is possible to appropriately employ, for example, the polymer described in Paragraphs [0011] to [0040] of JP2013-084947A.

(Electroconductive Nanocarbon Material)

In the invention, the electroconductive nanocarbon material that is used as the thermoelectric conversion material is not particularly limited, and a known nanocarbon material (carbon-containing electroconductive nanomaterial) can be used.

In addition, the size of the electroconductive nanomaterial is not particularly limited as long as the size is on a nanometer scale (smaller than 1 μm). For example, for a carbon nanotube, a carbon nanofiber, and the like described below, the average short diameter may be on a nanometer scale (for example, the average short diameter is 500 nm or smaller).

Specific examples of the above-described electroconductive nanocarbon material include carbon nanotubes (hereinafter, also referred to as “CNT”), carbon nanofibers, graphite, graphene, and carbon nanoparticles, and the electroconductive nanocarbon material may be used singly, or two or more kinds thereof may be used in combination.

Among these, the electroconductive nanocarbon material is preferably CNT since the thermoelectric characteristics become more favorable.

In addition, as CNT, it is possible to appropriately employ CNT described in, for example. Paragraphs [0017] to [0021] in WO2012/133314A or Paragraphs [0018] to [0022] in JP2013-095820A.

(Nanometal Material)

In the invention, the nanometal material that is used as the thermoelectric conversion material is not particularly limited, and it is possible to use, for example, a known nanometal material such as a metal nanowire for which Bi₂Te₃ is used.

(Binder)

As a binder for the thermoelectric conversion layer, a variety of known substances can be used.

Specific examples of a preferred binder include a styrene polymer, an acrylic polymer, polycarbonate, polyester, an epoxy resin, a siloxane polymer, polyvinyl alcohol, and gelatin.

Meanwhile, in the thermoelectric conversion module of the invention, the amount ratio between the binder and the thermoelectric conversion material in the thermoelectric conversion layer may be appropriately set depending on the materials being used, the required thermoelectric conversion efficiency, the viscosity of a solution or the concentration of solid contents which have an influence on printing, and the like.

Specifically, the mass ratio of “the thermoelectric conversion material to the binder” is preferably 90/10 to 10/90 and more preferably 75/25 to 40/60.

When the amount ratio between the binder and the thermoelectric conversion material is set in the above-described range, a preferred result is obtained from the viewpoint of a higher power generating efficiency, the impartment of printing adequacy, and the like.

(Other Components)

The thermoelectric conversion layer may contain other components in addition to the thermoelectric conversion material.

For example, the thermoelectric conversion layer may appropriately contain inorganic particles, an oxidation inhibitor, a light-fast stabilizer, a heat-resistant stabilizer, a plasticizer, a crosslinking agent, and the like. The content of these components is preferably 5% by mass or less, relative to the total mass of the material.

Examples of the oxidation inhibitor include IRGANOX 1010 (manufactured by Ciba-Geigy Japan Limited). SUMILIZER GA-80 (manufactured by Sumitomo Chemical Co., Ltd.), SUMILIZER GS (manufactured by Sumitomo Chemical Co., Ltd.), and SUMILIZER GM (manufactured by Sumitomo Chemical Co., Ltd.).

Examples of the light-fast stabilizer include TINUVIN 234 (manufactured by BASF). CHIMASSORB 81 (manufactured by BASF), and CYASORB UV-3853 (manufactured by Sun Chemical Company LTD.).

Examples of the heat-resistant stabilizer include IRGANOX 1726 (manufactured by BASF).

Examples of the plasticizer include ADEKACIZER RS (manufactured by Adeka Corp.).

(Solvent)

In the preparation of the thermoelectric conversion layer, it is possible to use an appropriate solvent.

The solvent may be any solvent capable of favorably dispersing or dissolving a composition of the thermoelectric conversion layer such as the thermoelectric conversion material, and it is possible to use water, an organic solvent, and a solvent mixture thereof. The solvent is preferably an organic solvent, and halogen-based solvents such as an alcohol and chloroform, polar organic solvents such as DMF, NMP, and DMSO, aromatic solvents such as chlorobenzene, dichlorobenzene, benzene, toluene, xylene, pyridine, tetrahydronaphthalene, and mesitylene, ketone-based solvents such as cyclohexanone, acetone, and methyl ethyl ketone, ether-based solvents such as diethyl ether, THF, t-butyl methyl ether, dimethoxyethane, and diglyme, and the like are preferably used.

In addition, the solvent is preferably degassed in advance. The dissolved oxygen level in the solvent is preferably set to 10 ppm or less. Examples of a degassing method include a method in which ultrasonic waves are radiated at a reduced pressure and a method in which an inert gas such as argon is bubbled.

Similarly, the solvent is preferably dehydrated in advance. The amount of moisture in the solvent is preferably set to 1,000 ppm or less and more preferably set to 100 ppm or less. As a method for dehydrating the dispersion medium, it is possible to use a well-known method such as the use of a molecular sieve or distillation.

(Method for Forming Thermoelectric Conversion Layer)

A method for forming the thermoelectric conversion layer in the thermoelectric conversion module of the invention is not particularly limited, and the thermoelectric conversion layer can be formed by applying a solution (a composition for forming the thermoelectric conversion layer) obtained by dispersing or dissolving the composition of the thermoelectric conversion layer in a solvent onto a substrate and forming a film.

A method for preparing the composition for forming the thermoelectric conversion layer is not particularly limited as long as the composition is prepared by mixing the thermoelectric conversion material and other components as necessary. An appropriate solvent may also be used. The composition can be prepared at normal temperature and normal pressure using a conventional mixing apparatus or the like. For example, the composition may be prepared by stirring or shaking various components in a solvent, and thereby dissolving or dispersing the components. In order to promote dissolution or dispersion, an ultrasonication treatment may be carried out.

A film-forming method is not particularly limited, and, for example, a known coating method such as spin coating, extrusion die coating, blade coating, bar coating, screen printing, stencil printing, roll coating, curtain coating, spray coating, dip coating, or an ink jet method can be used.

In addition, after the coating, a drying step is carried out as necessary. For example, the solvent can be volatilized and dried by blowing hot air.

In the invention, the film thickness of the thermoelectric conversion layer is preferably 0.1 μm to 1,000 μm and more preferably 1 μm to 300 μm from the viewpoint of imparting a temperature difference.

[Stress Relaxation Layer]

The stress relaxation layer in the thermoelectric conversion module of the invention is not particularly limited as long as the stress relaxation layer is capable of suppressing warping caused by the shrinkage of the thermoelectric conversion layer while being formed on the flexible substrate and adjusting the warping degree, but the stress relaxation layer is preferably bendable enough to coat or adhere to the flexible substrate.

In addition, as a material for the stress relaxation layer, a material having a higher shrinkage ratio than the flexible substrate is preferably used. When a material having a higher shrinkage ratio than the flexible substrate is used, it is possible to decrease the thickness of the stress relaxation layer. In addition, it is preferable to use a material having substantially the same shrinkage ratio as the shrinkage ratio of the thermoelectric conversion layer. When a material having substantially the same shrinkage ratio as the shrinkage ratio of the thermoelectric conversion layer is used, it becomes easy to adjust the warping degree, which is preferable.

As the above-described stress relaxation layer, it is possible to use, for example, a polymer material, an adhesive, or the like. In addition, it is also possible to use the same composition as the thermoelectric conversion layer or a composition obtained by removing a part (for example, the nanocarbon material) from the composition of the thermoelectric conversion layer as the stress relaxation layer. Alternatively, a heat-dissipating sheet may also be used as the stress relaxation layer.

The thickness of the stress relaxation layer is not particularly limited, but is preferably 1 μm to 5,000 μm since it is possible to appropriately suppress the warping of the thermoelectric conversion module and more preferably adjust the warping degree.

In addition, the area (the ratio to the area of the flexible substrate) of the stress relaxation layer is also not particularly limited and may be appropriately selected depending on the warping degree.

In addition, the stress relaxation layer may be formed on the flexible substrate before the formation of the thermoelectric conversion layer or may be formed after the formation of the thermoelectric conversion layer.

(Polymer Material)

The polymer material contained in the stress relaxation layer is not particularly limited, and a known polymer material can be used.

From the viewpoint of coatability to the flexible substrate and bendability, a siloxane polymer, a urethane polymer, a styrene polymer, an acryl polymer, a polyvinyl alcohol, gelatin, or the like is preferably used as the polymer material.

In addition, the stress relaxation layer may contain other components in addition to the polymer material.

(Heat-Dissipating Sheet)

The heat-dissipating sheet that is used as the stress relaxation layer is not particularly limited, and a commercially available heat-dissipating sheet can be used. For example, it is possible to use TC-50TXS2 manufactured by Shin-Etsu Chemical Co., Ltd., a hyper soft heat-dissipating material 5580H manufactured by Sumitomo 3M Limited, BFG20A manufactured by Denka Company Limited, or the like.

When a heat-dissipating sheet is used as the stress relaxation layer, it is possible to more preferably cool the low-temperature side (first electrode side) of the thermoelectric conversion element, and the thermoelectric efficiency further improves, which is preferable.

(Heat-Dissipating Fin)

Furthermore, a heat-dissipating fin consisting of a known material such as stainless steel, copper, or aluminum may be provided on the outside of the stress relaxation layer.

When a heat-dissipating fin is used, it is possible to more preferably cool the low-temperature side (first electrode side) of the thermoelectric conversion element, and the thermoelectric efficiency further improves, which is preferable.

### EXAMPLES

Hereinafter, the present invention will be explained in more detail by way of Examples, but the invention is not intended to be limited to these.

### Example 1-1

### Production of Thermoelectric Conversion Module

A thermoelectric conversion module having an embodiment illustrated in FIG. 1 was produced as Example 1-1.

(Formation of Thermoelectric Conversion Element)

7 g of an electroconductive polymer (poly-3-hexylthiophene (manufactured by Sigma-Aldrich Co. LCC., molecular weight: Mw20,000)) and 4 g of a single-layer CNT (ASP-100F, manufactured by Hanwha Nanotech Corporation, dispersion (the concentration of CNT: 60% by mass), the length of CNT: approximately 5 μm to 20 μm, the average diameter: approximately 1.0 nm to 1.2 nm) were added to 300 ml of ortho-dichlorbenzene and were dispersed in an ultrasonic water bath for 90 minutes, thereby obtaining a composition for forming the thermoelectric conversion layer (dispersion liquid (A)).

The dispersion liquid (A) was applied onto the electrode surface of a polyethylene terephthalate film (thickness: 16 μm) having a gold piece (thickness: 20 nm, width: 5 mm) as a first electrode on one surface using a stencil printing method (coating step) and was heated at 100° C. for 30 minutes, thereby removing the solvent (drying step). Furthermore, after the coating step and the drying step are repeated, the dispersion liquid was dried at room temperature in a vacuum for 10 hours, thereby forming a total of 240 thermoelectric conversion layers having a film thickness of 100 μm and a size of 12 mm×8 mm.

After that, all the elements were wired so as to be connected with each other in series using silver paste as a second electrode at the upper part of the thermoelectric conversion layer.

In the above-described manner, a total of 240 thermoelectric conversion elements were produced on a PET film having a size of 29.7 (cm)×21.0 (cm).

(Formation of Stress Relaxation Layer)

10 g of an electroconductive polymer (poly-3-hexylthiophene (manufactured by Sigma-Aldrich Co. LCC., molecular weight: Mw20,000)) was added to 300 ml of ortho-dichlorbenzene and was dissolved in an ultrasonic water bath, thereby obtaining a coating liquid B.

The coating liquid B was applied onto the entire surface of the PET film on a side opposite to the side on which the thermoelectric conversion elements were produced so that the dried film thickness reached 20 μm and was dried, thereby producing a thermoelectric conversion module of the invention.

The produced thermoelectric conversion module was left to stand on a flat surface and was fixed by placing a 1 cm-wide weight on the central part of one short side of the sample, the maximum value and the minimum value of the peeling degree on the other short side were measured, and the warping degree was measured from the average thereof. The warping degree was 4 cm.

### Example 1-2

A thermoelectric conversion module was produced in the same manner as in Example 1-1, except that the thickness of the stress relaxation layer was set to 50 μm.

In addition, the warping degree of the produced thermoelectric conversion module was 3 cm.

### Example 1-3

A thermoelectric conversion module was produced in the same manner as in Example 1-1, except that the thickness of the stress relaxation layer was set to 75 μm.

In addition, the warping degree of the produced thermoelectric conversion module was 1 cm.

### Example 1-4

A thermoelectric conversion module was produced in the same manner as in Example 1-1, except that the thickness of the stress relaxation layer was set to 13 μm.

In addition, the warping degree of the produced thermoelectric conversion module was 6 cm.

### Example 1-5

A thermoelectric conversion module was produced in the same manner as in Example 1-1, except that the thickness of the stress relaxation layer was set to 5 μm.

In addition, the warping degree of the produced thermoelectric conversion module was 8 cm.

### Comparative Example 1-1

A thermoelectric conversion module was produced in the same manner as in Example 1-1, except that the thickness of the stress relaxation layer was set to 100 μm.

The produced thermoelectric conversion module warped so as to become convex with respect to the thermoelectric conversion element side. Therefore, the warping degree was measured with the thermoelectric conversion element side facing downward. The warping degree was −8 cm.

### Comparative Example 1-2

A thermoelectric conversion module was produced in the same manner as in Example 1-1, except that the thickness of the stress relaxation layer was set to 82 μm.

The produced thermoelectric conversion module did not warp and was flat.

### Comparative Example 1-3

A thermoelectric conversion module was produced in the same manner as in Example 1-1, except that the stress relaxation layer was not provided.

The warping degree of the produced thermoelectric conversion module was 12 cm.

### Example 2-1

As Example 2-1, a thermoelectric conversion module was produced in the same manner as in Example 1-1, except that the thickness of the thermoelectric conversion layer was set to 200 μm, and a 0.5 mm-thick heat-dissipating sheet (manufactured by Sumitomo 3M Limited: a hyper soft heat-dissipating material 5589H) was used as the stress relaxation layer.

The warping degree of the produced thermoelectric conversion module was 3 cm.

### Example 2-2

A thermoelectric conversion module was produced in the same manner as in Example 2-1, except that the thickness of the stress relaxation layer (heat-dissipating sheet) was set to 1 mm.

The warping degree of the produced thermoelectric conversion module was 3 cm.

### Example 2-3

A thermoelectric conversion module was produced in the same manner as in Example 2-1, except that the thickness of the stress relaxation layer (heat-dissipating sheet) was set to 1.5 mm.

The warping degree of the produced thermoelectric conversion module was 2 cm.

### Example 2-4

A thermoelectric conversion module was produced in the same manner as in Example 2-1, except that the thickness of the stress relaxation layer (heat-dissipating sheet) was set to 2 mm.

The warping degree of the produced thermoelectric conversion module was 1 cm.

### Example 2-5

A thermoelectric conversion module was produced in the same manner as in Example 2-1, except that a 0.5 mm-thick heat-dissipating sheet (manufactured by Shin-Etsu Chemical Co., Ltd.: TC-50TX2) was used as the stress relaxation layer.

The warping degree of the produced thermoelectric conversion module was 2.5 cm.

### Comparative Example 2-1

A thermoelectric conversion module was produced in the same manner as in Example 2-1, except that the stress relaxation layer (heat-dissipating sheet) was not provided.

The warping degree of the produced thermoelectric conversion module was 14 cm.

### EVALUATION

For the respective produced thermoelectric conversion modules, the thermoelectric performance was evaluated using the following method.

<Measurement of Thermoelectric Characteristic Value (Thermoelectromotive Force S)>

The produced thermoelectric conversion module was wound in a cylindrical tube having a diameter of 15 cm with the thermoelectric conversion element side in contact with the tube so that the long side had a curvature, and the short side of the module was fixed to the tube using tape. The cylindrical tube was heated to 80° C., and the voltage generated from the thermoelectric conversion module was measured using a digital voltage measurement instrument.

The voltage was evaluated as a relative value with respect to the voltage generated in case in which the stress relaxation layer was not provided as the standard value (100). That is, in Example 1, the voltage was evaluated as a relative value with respect to the voltage of Comparative Example 1-3 which was assumed to be 100, and, in Example 2, the voltage was evaluated as a relative value with respect to the voltage of Comparative Example 2-1 which was assumed to be 100.

The results are shown in Tables 1 and 2.

TABLE 1

| | Thickness of | Thickness of | | |
|---|---|---|---|---|
| | thermoelectric | stress | Warping | Electro- |
| | conversion | relaxation | degree | motive |
| | layer μm | layer μm | cm | force |
| Example 1-1 | 100 | 20 | 4 | 138 |
| Example 1-2 | 100 | 50 | 3 | 133 |
| Example 1-3 | 100 | 75 | 1 | 132 |
| Example 1-4 | 100 | 13 | 6 | 145 |
| Example 1-5 | 100 | 5 | 8 | 123 |
| Comparative | 100 | 100 | −8 | 98 |
| Example 1-1 | | | | |
| Comparative | 100 | 82 | 0 | 100 |
| Example 1-2 | | | | |
| Comparative | 100 | — | 12 | 100 |
| Example 1-3 | | | | |

TABLE 2

| | Thickness of | Thickness of | | |
|---|---|---|---|---|
| | thermoelectric | stress | Warping | Electro- |
| | conversion | relaxation | degree | motive |
| | layer μm | layer mm | cm | force |
| Example 2-1 | 200 | 0.5 | 3 | 134 |
| Example 2-2 | 200 | 1 | 3 | 133 |
| Example 2-3 | 200 | 1.5 | 2 | 128 |
| Example 2-4 | 200 | 2 | 1 | 126 |
| Example 2-5 | 200 | 0.5 | 2.5 | 145 |
| Comparative | 200 | — | 14 | 100 |
| Example 2-1 | | | | |

As shown in Tables. 1 and 2, it is found that, in each of Examples 1-1 to 1-5 and 2-1 to 2-5 which had the stress relaxation layer, warped so as to become concave with respect to the thermoelectric conversion element side, and were the thermoelectric conversion module of the invention, the electromotive force was greater and the thermoelectric efficiency was higher compared with the thermoelectric conversion modules not provided with the stress relaxation layer (Comparative Examples 1-1 and 2-1) and the thermoelectric conversion modules that did not warp toward the thermoelectric conversion element side (Comparative Examples 1-2 and 1-3). This is considered to be because the thermoelectric conversion module warped so as to become concave with respect to the thermoelectric conversion element side, and thus the adhesiveness to the cylindrical tube (heat source) improved.

In addition, from the relationship between the warping degree and the electromotive force in each example, it is found that, when the thermoelectric conversion module has a certain warping degree, a greater electromotive force can be obtained and the thermoelectric characteristics improve.

From the above-described results, the effect of the invention is evident.

### EXPLANATION OF REFERENCES

10, 300: thermoelectric conversion module
12, 31: flexible substrate
14, 32: first electrode
16, 33: second electrode
18, 34: thermoelectric conversion layer
20, 20a to 20d, 35: stress relaxation layer
22, 30: thermoelectric conversion element

What is claimed is:

1. A thermoelectric conversion module comprising:
a flexible substrate; and
a thermoelectric conversion element having a first electrode, a thermoelectric conversion layer including an organic material, and a second electrode in this order,
wherein the thermoelectric conversion module has a stress relaxation layer that adjusts warping of the flexible substrate on a surface of the flexible substrate opposite to a side on which the thermoelectric conversion element is disposed and
warps so as to become concave with respect to a thermoelectric conversion element side.

2. The thermoelectric conversion module according to claim 1,
wherein the stress relaxation layer is a heat-dissipating sheet.

3. The thermoelectric conversion module according to claim 1,
wherein the stress relaxation layer includes the same material as the thermoelectric conversion layer.

4. The thermoelectric conversion module according to claim 2,
wherein the stress relaxation layer includes the same material as the thermoelectric conversion layer.

5. The thermoelectric conversion module according to claim 1,
wherein a stress relaxation force of the stress relaxation layer is anisotropic in a predetermined first direction and a direction orthogonal to the first direction.

6. The thermoelectric conversion module according to claim 4,
wherein a stress relaxation force of the stress relaxation layer is anisotropic in a predetermined first direction and a direction orthogonal to the first direction.

7. The thermoelectric conversion module according to claim 1,
wherein a warping degree of the thermoelectric conversion module is 50 μm to 80 mm.

8. The thermoelectric conversion module according to claim 6,
wherein a warping degree of the thermoelectric conversion module is 50 μm to 80 mm.

9. The thermoelectric conversion module according to claim 1,
wherein the thermoelectric conversion layer contains an electroconductive polymer.

10. The thermoelectric conversion module according to claim 8,
wherein the thermoelectric conversion layer contains an electroconductive polymer.

11. The thermoelectric conversion module according to claim 1,
wherein the thermoelectric conversion layer contains a carbon nanotube and a binder.

12. The thermoelectric conversion module according to claim 8,
wherein the thermoelectric conversion layer contains a carbon nanotube and a binder.

13. The thermoelectric conversion module according to claim 1,
wherein the flexible substrate is formed of an organic material.

14. The thermoelectric conversion module according to claim 12,
wherein the flexible substrate is formed of an organic material.

15. The thermoelectric conversion module according to claim 1,
wherein a thickness of the flexible substrate is 5 μm to 5,000 μm.

16. The thermoelectric conversion module according to claim 12,
wherein a thickness of the flexible substrate is 5 μm to 5,000 μm.
